(19) United States
(12) Patent Application Publication
(10) Pub. No.: US 2022/0164936 A1
(43) Pub. Date: May 26, 2022

(54) MANUFACTURING MANAGEMENT METHOD

(71) Applicant: NEC Corporation, Minato-ku, Tokyo (JP)

(72) Inventors: Takashi SHIBATA, Tokyo (JP); Toru TAKAHASHI, Tokyo (JP); Rui ISHIYAMA, Tokyo (JP); Keiko INOUE, Tokyo (JP); Kola WAMOTO, Tokyo (JP); Hiroyashi MIYANO, Tokyo (JP); Emi KITAGAWA, Tokyo (JP); Yasuhiko YOSHIDA, Tokyo (JP)

(73) Assignee: NEC Corporation, Minato-ku, Tokyo (JP)

(21) Appl. No.: 17/432,976

(22) PCT Filed: Feb. 27, 2019
(86) PCT No.: PCT/JP2019/007668

§ 371 Date: Aug. 23, 2021

(51) Int. Cl. G06T 7/00

(52) U.S. Cl. CPC G06T 7/001; G06T 2207/30108

(57) ABSTRACT

A manufacturing management device 100 includes an acquisition unit 121 that acquires unique information of a product from a captured image of the product for each manufacturing step included in a manufacturing process of the product, and acquires manufacturing state information representing a manufacturing state in the manufacturing step, and an association unit 122 that stores the unique information of the product and the manufacturing state information that are acquired in an identical manufacturing step in association with each other.

### TECHNICAL FIELD

The present invention relates to a manufacturing management method, a manufacturing management device, and a program.

### BACKGROUND ART

Recently, in a manufacturing premise of the manufacturing industry, manufacturing history such as machining and inspection of each of the products to be manufactured is accumulated and analyzed as big data, which are utilized to improve the quality management and the production efficiency, and also to improve the design and machining accuracy. In particular, product quality management is important. It is necessary to specify the factor of the quality evaluated for each product by tracking back the manufacturing history of each product.

In order to accumulate the manufacturing history of each product, it is necessary to identify an individual that is a product itself. That is, by acquiring individual identification information of a product flowing through the manufacturing line, and storing the individual identification information in association with the manufacturing state information, it is possible to acquire the manufacturing history.

Here, for individual identification of a product, the product may be given with a manufacturing number or a bar code, or attached with a tag such as a Radio Frequency IDentifier (RFID). However, in the case of performing individual identification using a manufacturing number, a bar code, or a tag as described above, it is necessary to apply it to each product, which causes a problem of a cost increase. Moreover, for a small product such as a screw, a bolt, or a tablet, there is a case where a manufacturing number, a bar code, or a tag cannot be given due to a restriction in the size or product characteristics. Furthermore, even for a product to which a bar code, a tag, can be given physically, a problem of impairing the appearance or design of the product may be caused.

To cope with it, in recent years, an object fingerprint authentication technology for performing individual identification using a fine pattern (object pattern) of a surface of a product has been proposed. Specifically, in the object fingerprint authentication technology, individual identification of a product is performed by acquiring a fine pattern that is naturally generated in the manufacturing process of the product such as a random pattern on a surface of a material, as an image with use of a capturing device such as a camera, and identifying the fine pattern.

Patent Literature 1 discloses an example of managing product quality using the object fingerprint authentication technology described above. In Patent Literature 1, a surface of a product is captured and surface pattern information is acquired, and the surface pattern information is stored in a database in association with relevant information of manufacturing such as manufacturing date/time, manufacturing conditions such as temperature and humidity at the time of manufacturing, and IDs of the manufacturing factory and the manufacturing line. Thereafter, in response to a request from a user or a distributor, the relevant information of manufacturing the product is specified by collating the surface pattern information of the actual product and the surface pattern information stored in the database.

Patent Literature 1: JP 2015-232853 A

### SUMMARY

However, in the technology described in Patent Literature 1, only rough information related to manufacturing such as manufacturing date/time, manufacturing conditions, and manufacturing place can be specified from the surface pattern information of the product. Therefore, if there are a plurality of manufacturing steps for a product, it is impossible to specify which step is the factor of the quality of the product. This causes a problem that the factor of the product quality cannot be specified in detail.

Therefore, an object of the present invention is to provide a manufacturing management method in which the problem described above, that is, a problem that it is impossible to specify the factor of the product quality in detail, can be solved.

A manufacturing management method according to one aspect of the present invention is configured to include

acquiring unique information of a product from a captured image of the product for each manufacturing step included in a manufacturing process of the product, and acquiring manufacturing state information representing a manufacturing state in the manufacturing step; and

storing the unique information of the product and the manufacturing state information, acquired in an identical manufacturing step, in association with each other;

when evaluating the product, acquiring the unique information of the product from the captured image of the product, and reading out the manufacturing state information of each manufacturing step stored in association with unique information that is identical to the acquired unique information; and

specifying a manufacturing state corresponding to the evaluation of the product, on the basis of the readout manufacturing state information of each manufacturing step.

Further, a manufacturing management method according to one aspect of the present invention is configured to include

acquiring unique information of a product from a captured image of the product captured in each manufacturing step included in a manufacturing process of the product, and acquiring manufacturing state information representing a manufacturing state in the manufacturing step; and

storing the unique information of the product and the manufacturing state information that are acquired in an identical manufacturing step in association with each other.

A manufacturing management device according to one aspect of the present invention is configured to include

an acquisition unit that acquires unique information of a product from a captured image of the product for each manufacturing step included in a manufacturing process of the product, and acquires manufacturing state information representing a manufacturing state in the manufacturing step, and

an association unit that stores the unique information of the product and the manufacturing state information that are acquired in an identical manufacturing step in association with each other.

A program according to one aspect of the present invention is a program for causing an information processing device to realize:

an acquisition unit that acquires unique information of a product from a captured image of the product for each manufacturing step included in a manufacturing process of the product, and acquires manufacturing state information representing a manufacturing state in the manufacturing step, and

an association unit that stores the unique information of the product and the manufacturing state information that are acquired in an identical manufacturing step in association with each other.

Since the present invention is configured as described above, it is possible to specify the factor of the product quality in detail.

### BRIEF DESCRIPTION OF DRAWINGS

FIG. 1 is a block diagram illustrating a configuration of a manufacturing system according to a first exemplary embodiment of the present invention.

FIG. 2 is a block diagram illustrating a configuration of the management device disclosed in FIG. 1.

FIG. 3 illustrates an example of information stored in the step data storage unit disclosed in FIG. 2.

FIG. 4 illustrates an example of information stored in the manufacturing parameter storage unit disclosed in FIG. 2.

FIG. 5 illustrates an example of information stored in the evaluation data storage unit disclosed in FIG. 2.

FIG. 6A illustrates an example of information stored in the evaluation data storage unit disclosed in FIG. 2.

FIG. 6B illustrates an example of information stored in the evaluation data storage unit disclosed in FIG. 2.

FIG. 7 illustrates an example of a product manufactured in the manufacturing system disclosed in FIG. 1.

FIG. 8 illustrates an example of a product manufactured in the manufacturing system disclosed in FIG. 1.

FIG. 9 is a diagram for explaining an operation of the management device disclosed in FIG. 1.

FIG. 10 is a flowchart illustrating an operation of the management device disclosed in FIG. 1.

FIG. 11 is a flowchart illustrating an operation of the management device disclosed in FIG. 1.

FIG. 12 is a block diagram illustrating a configuration of a manufacturing system according to a second exemplary embodiment of the present invention.

FIG. 13 illustrates an example of information stored in the manufacturing parameter storage unit disclosed in FIG. 12.

FIG. 14 illustrates an example of processing by the management device disclosed in FIG. 12.

FIG. 15 illustrates an example of processing by the management device disclosed in FIG. 12.

FIG. 16 is a diagram illustrating a configuration and an operation of a management device according to a third exemplary embodiment of the present invention.

FIG. 17 is a block diagram illustrating a hardware configuration of a manufacturing management device according to a fourth exemplary embodiment of the present invention.

FIG. 18 is a block diagram illustrating a configuration of the manufacturing management device according to the fourth exemplary embodiment of the present invention.

FIG. 19 is a flowchart illustrating an operation of the manufacturing management device according to the fourth exemplary embodiment of the present invention.

FIG. 20 is a flowchart illustrating an operation of the manufacturing management device according to the fourth exemplary embodiment of the present invention.

### EXEMPLARY EMBODIMENTS

### First Exemplary Embodiment

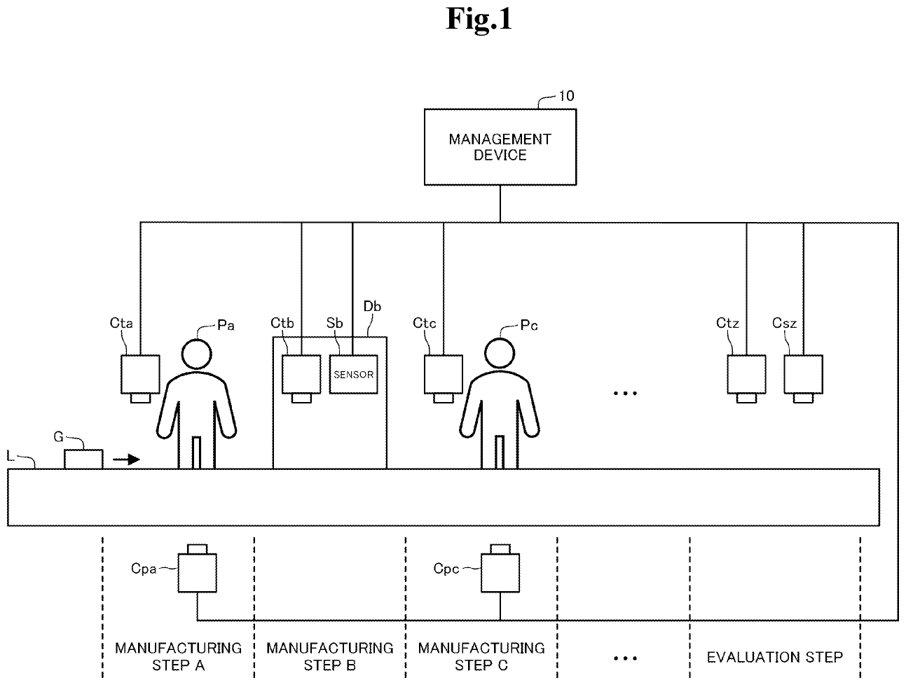

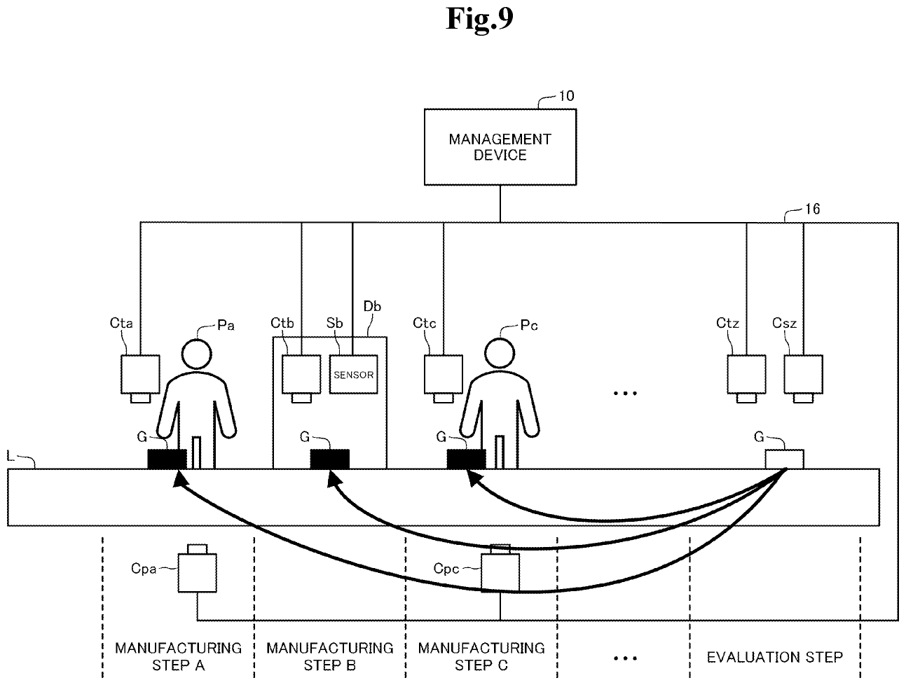

A first exemplary embodiment of the present invention will be described with reference to FIGS. 1 to 11. FIGS. 1 to 8 are diagrams for explaining a configuration of a manufacturing system, and FIGS. 9 to 11 are illustrations for explaining the processing operation of the management device.

### [Configuration]

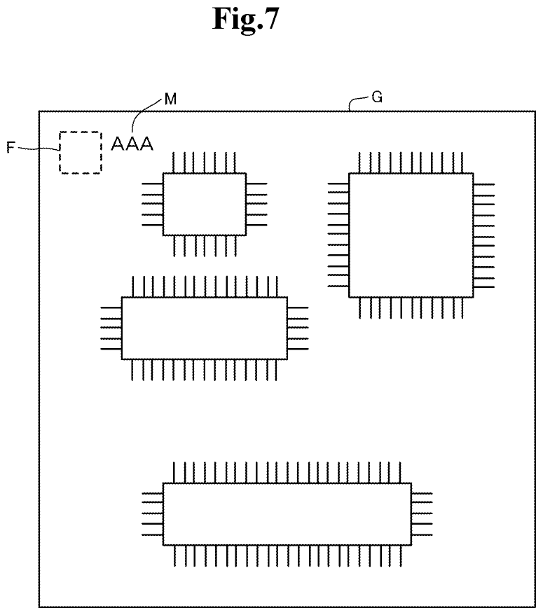

The manufacturing system of the present invention is constructed at a manufacturing premise of the manufacturing industry, and manufactures a given product G through the manufacturing process having been set. For example, it is assumed that the product G to be manufactured by the manufacturing system of the present embodiment is a semiconductor substrate as illustrated in FIG. 7. However, the product G to be manufactured by the manufacturing system of the present invention is not limited to a semiconductor substrate, and may be any product. Examples of the product G include electronic devices such as a laptop computer and a smartphone, household appliances such as a refrigerator and a cleaner, automobiles, batteries, tablet and packed medicines, ferrous materials, plastic materials, and the like.

The manufacturing process of manufacturing the product Gin the manufacturing system includes a plurality of manufacturing steps. For example, as illustrated in FIG. 1, a manufacturing line L set in the manufacturing system includes a plurality of manufacturing steps A, B, and C, and also includes an evaluation step of evaluating the quality of the finished product G. In the manufacturing steps A, B, and C, manufacturing work for manufacturing the product G is performed. For example, in the manufacturing step A, pretreatment work by a worker Pa is performed on the product G, in the manufacturing step B, heat-treatment work by a heat-treatment device is performed on the product G, and in the manufacturing step C, joining work by a worker Pc is performed on the product G, respectively. Further, in the evaluation step, quality evaluation through image processing of an image in which the product G is captured is performed. Note that the contents in the respective steps as described above performed in the manufacturing line L are examples. For example, in the case of producing chemical products such as pharmaceutical products, any work may be performed such as medicine injection work and stirring work. Further, the manufacturing line L may include only one manufacturing step or a larger number of manufacturing steps, without being limited to the number of manufacturing steps described above.

The manufacturing system of the present invention has, particularly for quality management of the product G, a function of identifying each product G conveyed through the manufacturing line L and storing the manufacturing state of each product G in each manufacturing step. Therefore, it is indispensable to use the technology for identifying each product G. In the present embodiment, an object fingerprint authentication technology for performing individual identification using a fine pattern (object fingerprint) on a surface of the product G is used.

Here, an object fingerprint authentication technology will be briefly described. In general, industrial products of the same specification are manufactured using manufacturing devices of the same specification so as not to have variations. However, even in mechanical components applied with cutting processing with high accuracy and components manufactured from the same mold, when the surfaces of the products are enlarged using a microscope under a specific illumination condition, the pieces of unevenness on the surfaces slightly differ from each other individually, which can be observed as different patterns. Such a fine pattern is of a level unrelated to the performance and the quality of a product and a component, and each has unique different feature. Therefore, the individual difference can be recognized by an image. That is, like a living thing, an industrial product also has a unique fingerprint individually, and it is possible to perform individual identification using such an object fingerprint.

Specifically, when an object fingerprint is extracted from a product, for example, a surface of a product is captured under a specific illumination condition, and from the captured image, a location where a change in the luminance is steep and the position is stably obtained is determined as a feature point. Then, by putting a local luminance pattern around the feature point into data as a feature amount, it is extracted as an object fingerprint of the product. Then, in the case of collating object fingerprints for checking whether or not they are identical products, it is performed by verifying consistency in the geometric arrangement of the feature points. For example, from the object fingerprints to be collated with each other, feature points in which the difference between the feature amounts becomes minimum is obtained as a pair, and from the obtained pair groups, only pair groups in which a relative positioning relationship with another feature point does not contradict are extracted. Then, a collation score S=ninlier/Ntotoal is calculated, where Ntotoal represents the number of extracted feature points, and ninlier represents the number of feature point pairs in which the geometric arrangement is correct. When the collation score is higher than a given threshold, it can be determined that the product from which the collated object fingerprint is extracted is an identical individual. Note that the object fingerprint extraction method and the collation method described above are just examples, and any methods may be used.

Next, the configuration of the manufacturing system will be further described. In the manufacturing steps A, B, and C and the evaluation step, the manufacturing system has cameras Cta, Ctb, Ctc, and Ctz for capturing an object fingerprint that is unique information of the product G. Each of the cameras Cta, Ctb, Ctc, and Ctz is installed so as to capture a partial surface for extracting the object fingerprint of the product G under a specific illumination condition, and transmits a captured tracking image to the management device 10. For example, in the present embodiment, each of the cameras Cta, Ctb, Ctc, and Ctz is installed to capture at least an image near the corner of a position where a specific mark M is located, among the four corners of a semiconductor substrate that is the product G illustrated in FIG. 7.

Further, in each of the manufacturing steps A, B, and C, the manufacturing system has a manufacturing state acquisition device that acquires information serving as the basis for acquiring a parameter representing the manufacturing state in each of the manufacturing steps. Upon acquiring information serving as the basis for a parameter representing the manufacturing state in each manufacturing step, the manufacturing state acquisition device transmits the information to the management device 10. For example, in the manufacturing step A, in order to acquire “worker's name” that is a parameter representing the manufacturing state, the camera Cpa for capturing an image of the worker Pa is provided as a manufacturing state acquisition device. Further, in the manufacturing step B, in order to acquire “temperature” at the time of heat treatment by the heat-treatment device Db as a parameter representing the manufacturing state, a temperature sensor Sb for measuring the temperature inside the heat-treatment device Db is provided as a manufacturing state acquisition device. Further, in the manufacturing step C, in order to acquire “working time” by the worker Pc as a parameter representing the manufacturing state, the camera Cpc for capturing the work of the worker Pc is provided as a manufacturing state acquisition device.

In the manufacturing system, in the evaluation step, a camera Csz for capturing the entire product G is provided so as to evaluate the quality of the manufactured product G. The camera Csz is installed to capture the entire product G so as to be able to detect information for evaluating the quality such as whether or not there is a crack in the product G, and transmits a captured image for evaluation to the management device 10.

Note that the parameters representing the manufacturing states acquired in the manufacturing steps A, B, and C by are not limited to those described above, and may be any parameters representing the manufacturing states. For example, parameters representing the manufacturing states may include a manufacturing step name, humidity at the time of manufacturing, a state of a tool used in the manufacturing step, and the like. Accordingly, the information serving as the basis for acquiring the parameters in the manufacturing steps A, B, and C is not limited to the images of the workers and the temperature at the time of heat treatment, and may be any information if it is information from which parameters representing manufacturing states set in advance can be acquired. Further, the evaluation step is not limited to performing quality evaluation of the product G on the basis of images for evaluation. For example, quality evaluation using heat distribution by thermography and quality evaluation by visual inspection by a worker may be performed, and such an evaluation result may be input to the management device 10.

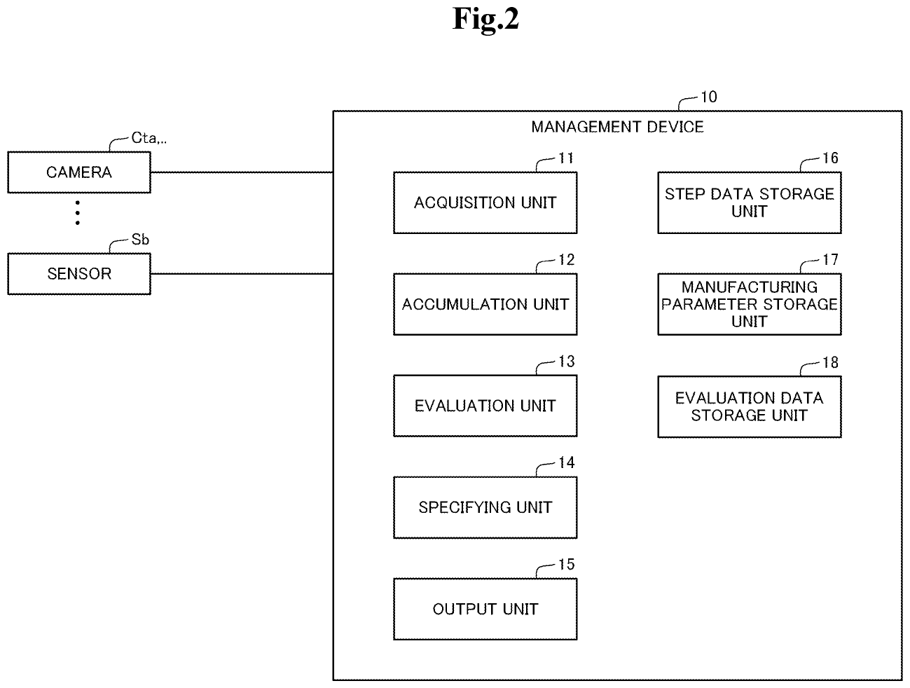

As illustrated in FIG. 1, the manufacturing system also includes the management device 10. The management device 10 is configured of one or a plurality of information processing devices each having an arithmetic unit and a storage unit. As illustrated in FIG. 2, the management device 10 includes an acquisition unit 11, an accumulation unit 12, an evaluation unit 13, a specifying unit 14, and an output unit 15 that are constructed by execution of a program by the arithmetic unit. The management device 10 also includes a step data storage unit 16, a manufacturing parameter storage unit 17, and an evaluation data storage unit 18 that are formed in the storage unit. Hereinafter, each configuration will be described in detail.

The acquisition unit 11 acquires tracking images captured by the cameras Cta, Ctb, and Ctc provided to the manufacturing steps A, B, and C respectively, and extracts and acquires the object fingerprint that is unique information of the product G from each of the tracking images. In the present embodiment, first, from a tracking image in which at least a part of a surface of the product G is captured, the acquisition unit 11 specifies an area near the corner where a specific mark M is positioned, among the four corners of a semiconductor substrate that is the product G, as an object fingerprint area F. Specifically, the acquisition unit 11 detects the specific mark M from the tracking image in which the product G is shown as illustrated in FIG. 7, and specifies an area of the position separated by a specific distance from the edge forming the corner where the mark M is positioned, as the object fingerprint area F. Then, the acquisition unit 11 puts the pattern of the specified object fingerprint area F into data as a feature amount, and extracts it as the object fingerprint of the product G. Thereby, the object fingerprint can be extracted from the identical locations on the surface of the product G captured in the manufacturing steps A, B, and C.

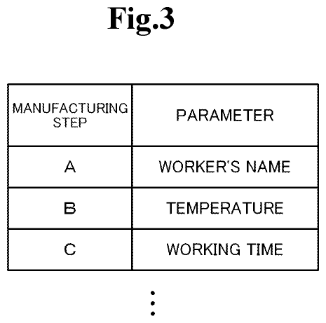

The acquisition unit 11 also acquires information of images representing the manufacturing states and measurement values from the cameras Cpa and Cpc and the sensor Sb provided to the manufacturing steps A, B, and C as manufacturing state acquisition devices, and from such information, acquires parameters representing the manufacturing states in the manufacturing steps A, B, and C. At that time, as illustrated in FIG. 3, the acquisition unit 11 acquires the parameters in the manufacturing steps on the basis of a correspondence table of the manufacturing steps and the parameters previously stored in the step data storage unit 16.

Specifically, In the case of the manufacturing step C, since the acquisition unit 11 is provided so as to acquire “worker's name” as a parameter, from a manufacturing state image acquired from the camera Cpa provided to the manufacturing step A, the worker's name of the worker working in the manufacturing step A is specified. At that time, in the management device 10, face information of a worker and the worker's name are previously registered in association with each other, and the worker's name can be specified by collating the registered face information with the face image shown in the image acquired from the camera Cpa. Note that the acquisition unit 11 is not necessarily limited to acquire the worker's name by the method described above. It may acquire the worker's name by any methods. For example, the acquisition unit 11 may specify the worker's name when information specifying the worker is input from an input device provided to the manufacturing step A, or specify and acquire the worker's name from registration information in which the worker's name of the worker who works in the manufacturing step A has been registered in the management device 10 in advance.

Further, in the case of the manufacturing step B, since it is set to acquire “temperature” as a parameter, the acquisition unit 11 acquires the temperature obtained from the sensor Sb provided to the manufacturing step B as “temperature” at the time of heat treatment by the heat-treatment device Db in the manufacturing step B. Note that the acquisition unit 11 is not necessarily limited to acquire the temperature by the method described above. It may acquire the temperature by any methods.

In the case of the manufacturing step C, since it is set to acquire “working time” as a parameter, the acquisition unit 11 acquires the working time of the worker Pc who is in a manufacturing work in the manufacturing step C, from the manufacturing state image acquired from the camera Cpc provided to the manufacturing step C. Here, the acquisition unit 11 analyzes the operation of the worker Pc in the manufacturing state information, detects a preset operation as the working operation, and acquires the time during which the working operation is performed as the working time. Note that the acquisition unit 11 is not necessarily limited to acquire the working time by the method described above. It may acquire the working time by any methods. For example, in the case where a working tool provided to the manufacturing step C is connected to the management device 10 and the operation time of such a working tool can be measured by the management device 10, such a working time may be acquired as the working time of the worker.

Note that the parameters acquired in the manufacturing steps A, B, and C by the acquisition unit 11 are not limited to those described above, and may be any parameters representing the manufacturing states. For example, the parameters acquired by the acquisition unit 11 may include a manufacturing step name, humidity at the time of manufacturing, a state of a tool used in the manufacturing step, and the like, and may be acquired by any methods.

The accumulation unit 12 (association unit) stores the object fingerprint of the product G acquired by the acquisition unit 11 described above and the parameter representing the manufacturing state of the product G in the manufacturing parameter storage unit 17, in association with each other. Here, the accumulation unit 12 stores the object fingerprint and the parameter acquired in the same manufacturing step, in association with each other. That is, the accumulation unit 12 associates the object fingerprint and the parameter acquired by the acquisition unit 11 as described above at almost the same timing. Further, when the object fingerprints of the product G acquired in different manufacturing steps match, the accumulation unit 12 collectively store the parameters acquired in the respective manufacturing steps in association with one object fingerprint. Thereby, the parameters representing the manufacturing states in the respective manufacturing steps of the same product G can be collectively stored in association with one object fingerprint.

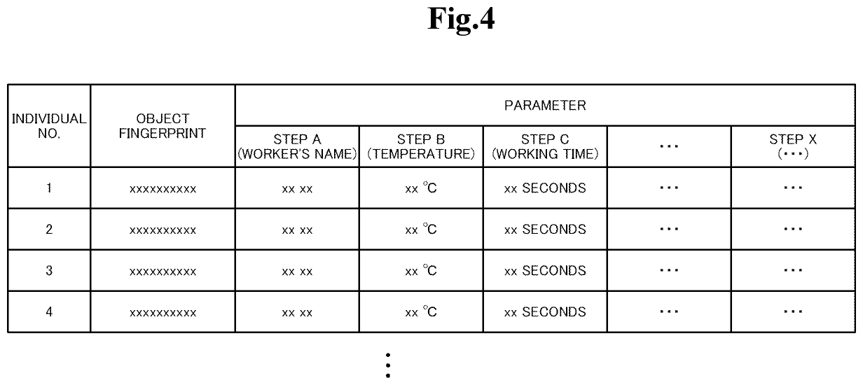

Specifically, the accumulation unit 12 acquires an object fingerprint and a parameter from the acquisition unit 11, and when an object fingerprint that is identical to such an object fingerprint is not stored in the manufacturing parameter storage unit 17, gives a new individual number, and associates the object fingerprint and the parameter with the individual number and stores them. Meanwhile, when an object fingerprint that is identical to the acquired object fingerprint is stored in the manufacturing parameter storage unit 17, the accumulation unit 12 stores the parameter by additionally associating it with the individual number associated with the stored object fingerprint. Thereby, as illustrated in FIG. 4, one individual number is given to one object fingerprint, and further, a parameter of each working step is stored in association therewith.

The evaluation unit 13 acquires a tracking image captured by the camera Ctz provided to the evaluation step, and extracts and acquires the object fingerprint that is unique information of the product G from the tracking image. The method of extracting the object fingerprint is similar to the method of extraction by the acquisition unit 11 as described above. Then, the evaluation unit 13 checks whether or not an object fingerprint identical to the object fingerprint acquired from the product G in the evaluation step is stored in the manufacturing parameter storage unit 17. When an object fingerprint identical to the object fingerprint acquired from the product G in the evaluation step is stored in the manufacturing parameter storage unit 17, the evaluation unit 13 reads the individual number given to the identical object fingerprint, and specifies it as the individual number of the product Gin the evaluation step.

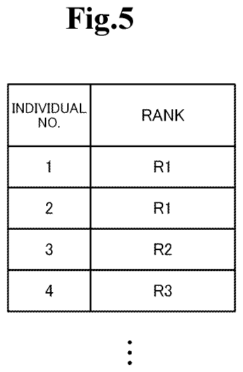

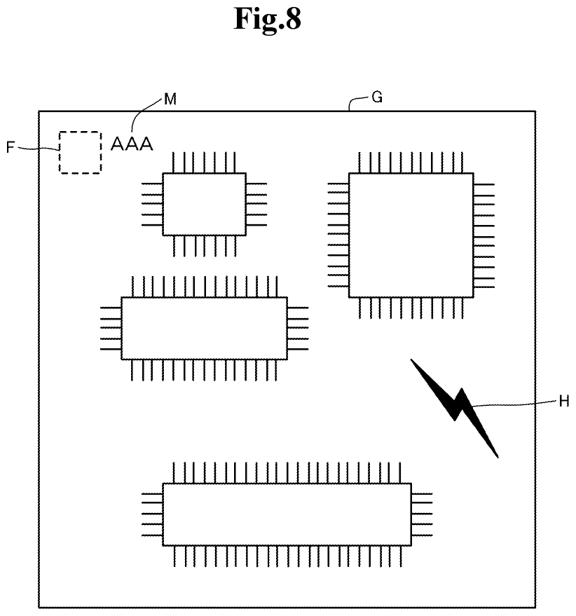

Further, the evaluation unit 13 acquires an evaluation image showing the entire product G captured by the camera Csz for evaluation provided to the evaluation step, and analyzes the evaluation image to evaluate the quality of the product G. For example, as illustrated in FIG. 8, the evaluation unit 13 detects a crack H in the product G and detects the length, width, position, and the like of the crack H from the evaluation image to thereby evaluate the quality of the product Gin a plurality of levels. Then, the evaluation unit 13 stores the evaluation result in the evaluation data storage unit 18 while associating it with the individual number specified from the object fingerprint acquired at almost the same timing as the evaluation image used for quality evaluation. For example, as illustrated in FIG. 5, the evaluation unit 13 ranks the evaluation of the product Gin a plurality of levels such as R1, R2, and R3, and stores it in the evaluation data storage unit 18 in association with the individual number. In that case, it is assumed that evaluation is higher as the numerical value of the rank is smaller, and evaluation is lower as the numerical value of the rank is larger. For example, in the present embodiment, it is assumed that ranks R1 and R2 represent quality of a normal condition and rank R3 represents quality of an abnormal condition. Note that the evaluation unit 13 does not necessarily evaluate the product G in a plurality of levels. The evaluation unit 13 may evaluate the quality of the product G by detecting the product G in a specific state such as only detecting that the product G is in an abnormal condition.

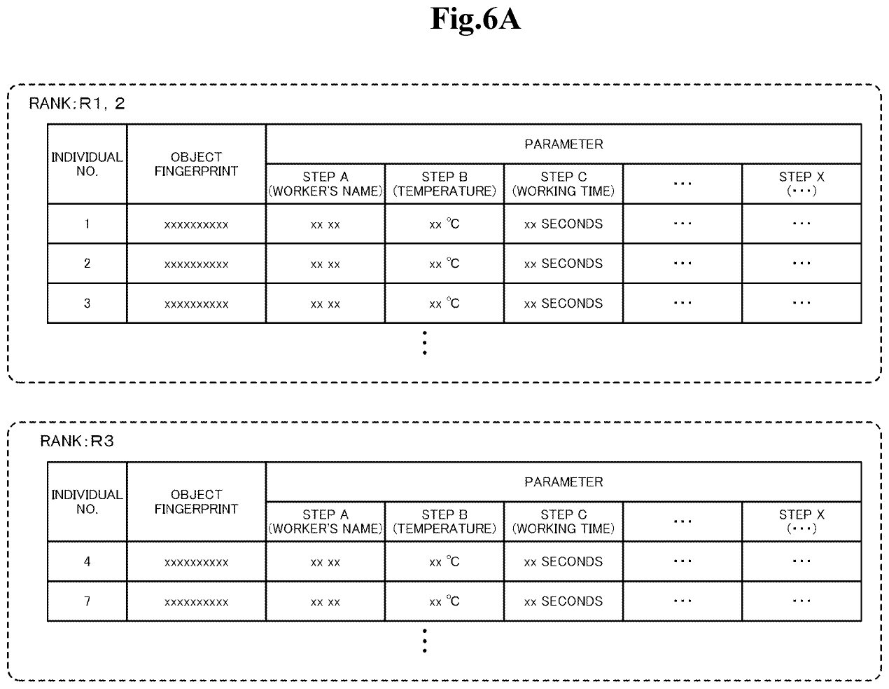

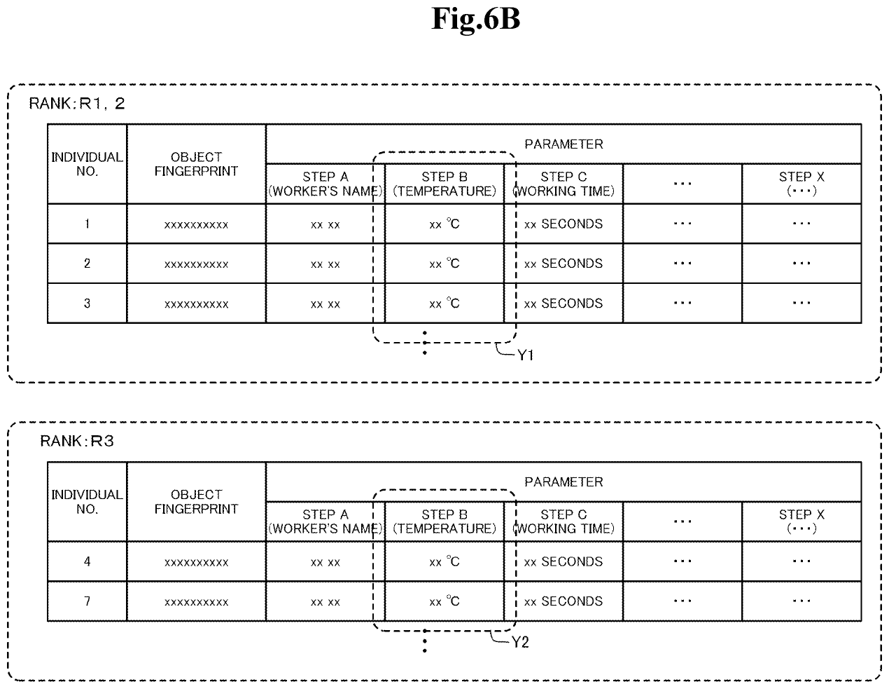

Then, since the evaluation of the product G is associated with the individual number as described above, from the individual number, the evaluation unit 13 can read the parameter representing the manufacturing state in the manufacturing step of the product G from the manufacturing parameter storage unit 17. For example, as illustrated in FIG. 5, it is assumed that an object fingerprint identical to the object fingerprint of the product G evaluated as rank R3, that is, in an abnormal condition, is registered with the individual number “4”. In that case, the evaluation unit 13 reads information of the individual number “4” from the manufacturing parameter storage unit 17 as illustrated in the lower part of FIG. 6A. As described above, by reading out the information of the product G from the manufacturing parameter storage unit 17, as indicated by the arrows in FIG. 9, it is possible to retroactively specify the parameters representing the manufacturing states in the respective manufacturing steps A, B, and C of the product G evaluated as an abnormal condition in the evaluation step.

In the present embodiment, while the evaluation unit 13 evaluates the quality of the product G from the evaluation image in which the product G is captured, evaluation may be performed by any methods such as quality evaluation using heat distribution by thermography. Further, without being limited to automatic evaluation of the quality of the product G through image processing, the evaluation unit 13 may receive an input of an evaluation result manually performed such as visual observation by a worker in the evaluation step.

The evaluation unit 13 also reads out parameters representing the manufacturing stats in the respective manufacturing steps of the product G, for each evaluation of the product G. For example, as illustrated in FIG. 6A, the evaluation unit 13 reads out the parameters of individual numbers corresponding to the product G of the ranks R1 and R2 evaluated as in a normal condition, and parameters of individual numbers corresponding to the product G of the rank R3 evaluated as in an abnormal condition, separately, and stores them in the evaluation data storage unit 18. Thereby, it is possible to compare the parameters during the manufacturing steps of the product G evaluated as in a normal condition with the parameters during the manufacturing steps of the product G evaluated as in an abnormal condition, and recognize the difference between them.

The specifying unit 14 specifies manufacturing states such as parameters and manufacturing steps serving as a factor of evaluation of the product G, on the basis of the evaluation of the product G by the evaluation unit 13 as described above, and the parameters representing the manufacturing states in the manufacturing steps of the product G. In the present embodiment, the specifying unit 14 specifies a correlation between the content of evaluation of the product G and the parameter of each of the manufacturing steps, on the basis of the parameter of each evaluation of the product G illustrated in FIG. 6A that is read and stored in the evaluation data storage unit 18 by the evaluation unit 13. As an example, the parameters of the product G of the ranks R1 and R2 evaluated as in a normal condition illustrated in the upper part of FIG. 6A is compared with the parameters of the individual numbers corresponding to the product G of the rank R3 evaluated as in an abnormal condition illustrated in the lower part of FIG. 6A, separately, and stores them in the evaluation data storage unit 18. Here, as indicated by reference signs Y1 and Y2 in FIG. 6B, when there is a difference in “temperature” that is a parameter of the manufacturing step B, it is specified that the parameter “temperature” has a correlation with the evaluation of the product G. That is, it is specified that the factor of the product G being in an abnormal condition is “temperature” at the time of heat treatment in the manufacturing step B.

Further, the specifying unit 14 may specify a range of values of “temperature” that may cause an abnormal condition, from the “temperature” of the product G of the rank R3 specified as a parameter having a correlation with the evaluation of an abnormal condition. Further, the specifying unit 14 may identify a range of values of “temperature” that may lead to best quality, from the “temperature” of the product G of the rank R1 evaluated as best quality of the normal condition. Then, the specifying unit 14 stores the parameter having a correlation with evaluation of the product G specified as described above and the value of the operation data corresponding to the evaluation, in the evaluation data storage unit 18.

In the above description, the case where the specifying unit 14 specifies that the parameter having a correlation with the evaluation of the product G is “temperature” in the manufacturing step B has been described as an example. However, there is a case where another parameter in another manufacturing step is specified, of course. For example, there is a case where the parameter having a correlation with evaluation of the product G being in an abnormal condition is specified as “worker's name” in the manufacturing step A, or a case where it is specified as “working time” in the manufacturing step C. Moreover, the specifying unit 14 may specify two or more parameters as parameters having a correlation with evaluation of the product G.

The output unit 15 outputs, from an output device such as a display device, a parameter in each of the manufacturing steps of the product G read out by the evaluation unit 13 as described above, or a parameter having a correlation with the evaluation of the product G specified by the specifying unit 14.

### [Operation]

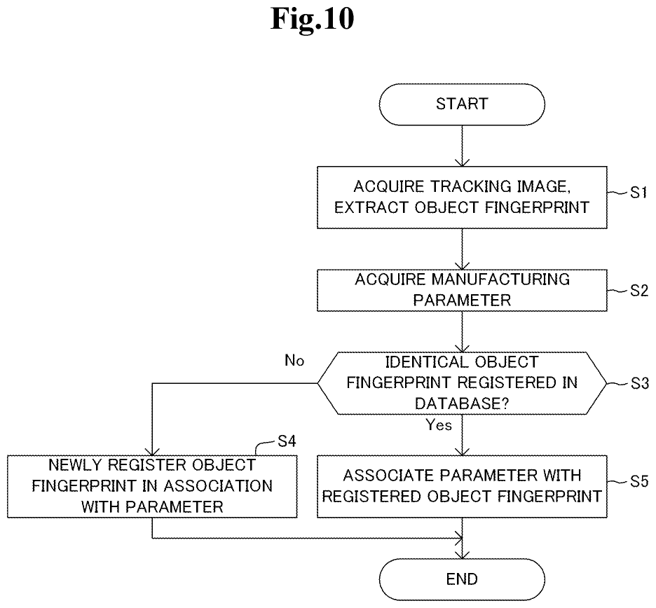

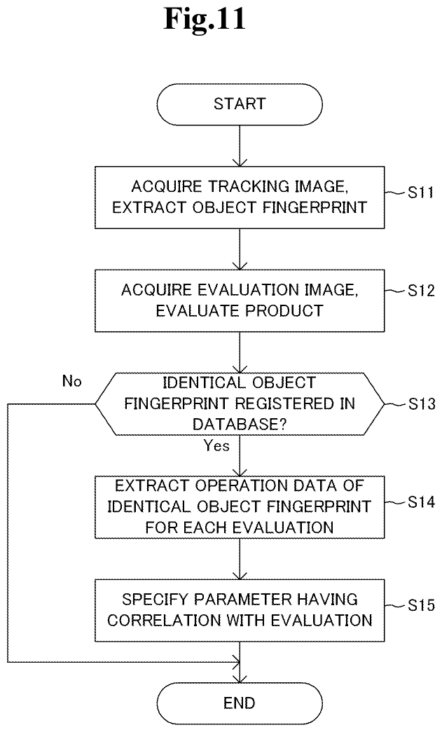

Next, operation of the management device 10 as described above will be described with reference to the flowcharts of FIGS. 10 and 11 mainly. First, with reference to the flowchart of FIG. 10, description will be given on an operation of accumulating parameters representing manufacturing states in the manufacturing steps of the product G manufactured in the manufacturing line L.

The management device 10 first acquires a tracking image captured by the camera Cta provided to the manufacturing step A that is the first manufacturing step. Then, the management device 10 extracts and acquires an object fingerprint that is unique information of the product G from the tacking image acquired in the manufacturing step A (step S1). At the almost same timing, the management device 10 acquires a manufacturing state image from the camera Cpa provided as a manufacturing state acquisition device in the manufacturing step A. Then, from the manufacturing state image acquired in the manufacturing step A, the management device 10 analyzes the face information of the worker to specify the worker's name, and acquires “worker's name” that is a parameter representing the working state in the manufacturing step A (step S2).

Then, the management device 10 checks whether or not an object fingerprint identical to the object fingerprint of the product G acquired in the manufacturing step A has been stored in the manufacturing parameter storage unit 17 (step S3). At this point of time, since the manufacturing step A is the first manufacturing step for the product G, the object fingerprint of the product G is not stored in the manufacturing parameter storage unit 17 (No at step S3). Therefore, the management device 10 newly registers the object fingerprint of the product G acquired in the manufacturing step A, and assigns a new individual number to the object fingerprint. Further, the management device 10 associates the newly assigned individual number with the object fingerprint and the “worker's name” that is a parameter acquired in the manufacturing step A, and stores them in the manufacturing parameter storage unit 17 (step S4).

Then, it is assumed that the product G in which the manufacturing work has been completed in the manufacturing step A as described above proceeds to the manufacturing step B that is the next manufacturing step. In this step, the management device 10 first acquires a tracking image captured by the camera Ctb provided to the manufacturing step B. Then, the management device 10 extracts and acquires an object fingerprint that is unique information of the product G from the tacking image acquired in the manufacturing step B (step S1). At the almost same timing, the management device 10 acquires “temperature” at the time of heat processing by the heat processing device in the manufacturing step B, from the sensor Sb provided as a manufacturing state acquisition device in the manufacturing step B.

Then, the management device 10 checks whether or not an object fingerprint identical to the object fingerprint of the product G acquired in the manufacturing step B has been stored in the manufacturing parameter storage unit 17 (step S3). Here, since the manufacturing step A has been completed for the product G, the object fingerprint of the product G has been stored in the manufacturing parameter storage unit 17 (Yes at step S3). Therefore, the management device 10 associates “temperature” that is the parameter acquired in the manufacturing step B with the individual number assigned to the object fingerprint that is identical to the object fingerprint of the product G acquired in the manufacturing step B, and stores it in the manufacturing parameter storage unit 17 (step S5). Thereby, the parameters acquired in the manufacturing step A and the manufacturing step B respectively are associated with the object fingerprint of the product G.

Then, it is assumed that the product G in which the manufacturing work has been completed in the manufacturing step B proceeds to the manufacturing step C that is the next manufacturing step. In this step, the management device 10 acquires a tracking image captured by the camera Ctc provided to the manufacturing step C. Then, the management device 10 extracts and acquires an object fingerprint that is unique information of the product G from the tacking image acquired in the manufacturing step C (step S1). At the almost same timing, the management device 10 acquires a manufacturing state image from the camera Cpc provided as a manufacturing state acquisition device in the manufacturing step C. Then, the management device 10 analyzes the operation of the worker Pc who is performing a manufacturing work in the manufacturing step C from the manufacturing state image acquired in the manufacturing step C, detects a preset operation as a work operation, and acquires the time in which the work operation is performed as “working time” that is a parameter representing the working state in the manufacturing step C (step S2).

Then, the management device 10 checks whether or not an object fingerprint identical to the object fingerprint of the product G acquired in the manufacturing step C has been stored in the manufacturing parameter storage unit 17 (step S3). Here, since the manufacturing steps A and B have been completed for the product G, the object fingerprint of the product G has been stored in the manufacturing parameter storage unit 17 (Yes at step S3). Therefore, the management device 10 associates the “working time” that is the parameter acquired in the manufacturing step C with the individual number assigned to the object fingerprint that is identical to the object fingerprint of the product G acquired in the manufacturing step C, and stores it in the manufacturing parameter storage unit 17 (step S5). Thereby, the parameters acquired in the manufacturing steps A, B, and C respectively are associated with the object fingerprint of the product G.

If there is another manufacturing step thereafter, the management device 10 stores the parameter acquired in each manufacturing step in association with the individual number of the object fingerprint that is identical to the object fingerprint acquired in each manufacturing step, as similar to the above-described cases. Thereby, as illustrated in FIG. 4 for example, the parameter of each manufacturing step is associated with the individual number of each product G specified by the object fingerprint, and is accumulated in the manufacturing parameter storage unit 17.

Next, an operation when the product G proceeds to the evaluation step will be described with reference to the flowchart of FIG. 11. The management device 10 acquires a tracking image captured by the camera Ctz provided to the evaluation step. Then, the management device 10 extracts and acquires an object fingerprint that is unique information of the product G, from the tacking image acquired in the evaluation step (step S11).

Further, at almost the same timing, the management device 10 acquires an evaluation image showing the entire product G captured by the camera Csz for evaluation provided to the evaluation step, and analyzes the evaluation image to evaluate the quality of the product G (step S12). For example, as illustrated in FIG. 8, the evaluation unit 13 detects a crack H caused in the product G and detects the length, width, position, and the like of the crack H from the evaluation image to thereby evaluate the quality of the product G in a plurality of levels, and ranks it as illustrated in FIG. 5.

Then, the management device 10 checks whether or not an object fingerprint identical to the object fingerprint of the product G acquired in the evaluation step has been stored in the manufacturing parameter storage unit 17 (step S13). Here, since the manufacturing steps have been completed for the product G, the object fingerprint of the product G has been stored in the manufacturing parameter storage unit 17 (Yes at step S13). Then, the management device 10 reads, from the manufacturing parameter storage unit 17, the parameters representing the work operations in the manufacturing steps associated with the individual number assigned to the object fingerprint that is identical to the object fingerprint of the product G acquired in the evaluation step (step S14). Note that the management device 10 may read only the parameter of the product G whose quality is currently evaluated in the evaluation step from the manufacturing parameter storage unit 17. Thereby, a parameter in each manufacturing step of the product G that is evaluated that an abnormal condition has occurred in the evaluation step can be checked.

Further, as illustrated in FIG. 6A, for each evaluation of the product G, the management device 10 reads the parameters representing the manufacturing states in the manufacturing steps of the product G from the manufacturing parameter storage unit 17 (step S14). Then, with use of the readout parameters for each evaluation of the product G, the management device 10 specifies the manufacturing states including the parameters and the manufacturing steps serving as the factor of the evaluation of the product G (step S15). For example, the management device 10 compares the parameters of a product G group that is evaluated to be in a normal condition with the parameters of a product G group that is evaluated to be in an abnormal condition, and specify the correlation between the content of evaluation of the product G and the parameter of each manufacturing step, as indicated by the reference signs Y1 and Y2 of FIG. 6B. Then, the management device 10 stores the parameter specified to have a correlation with the content of evaluation in the evaluation data storage unit 18, and outputs it.

As described above, in the present embodiment, in each manufacturing step of the product G, the object fingerprint that is unique information of the product G and the parameters representing the manufacturing states in the manufacturing steps are acquired, and the object fingerprint and the parameter acquired in the same manufacturing step are stored in association with each other. Therefore, the parameters in the manufacturing steps of the same product G can be collectively stored in association.

Then, in the present embodiment, the object fingerprint of the product G is acquired even in the evaluation step of the product G. Thereby, with use of such an object fingerprint, by reading out the parameter at the time of each manufacturing step of the product G stored in association with the identical object fingerprint, it is possible to check the parameter of each manufacturing step corresponding to the evaluation of the product retroactively.

Further, in the present embodiment, through comparison between parameters at the time of each manufacturing step of the products G having different evaluation, a correlation between the evaluation of the product G and the parameter is specified. Thereby, it is possible to specify the factor in the manufacturing steps of the quality of the product G in detail. Then, by reflecting the specified factor to the subsequent manufacturing steps, it is possible to improve the quality of the product.

Note that while an object fingerprint is used as unique information of the product G, it is not necessarily limited to use an object fingerprint as unique information. For example, in the case where it is easy to assign identification information such as a barcode to the product G, it is possible to extract identification information such as a barcode from an image in which the product G is captured and use it as unique information.

### Second Exemplary Embodiment

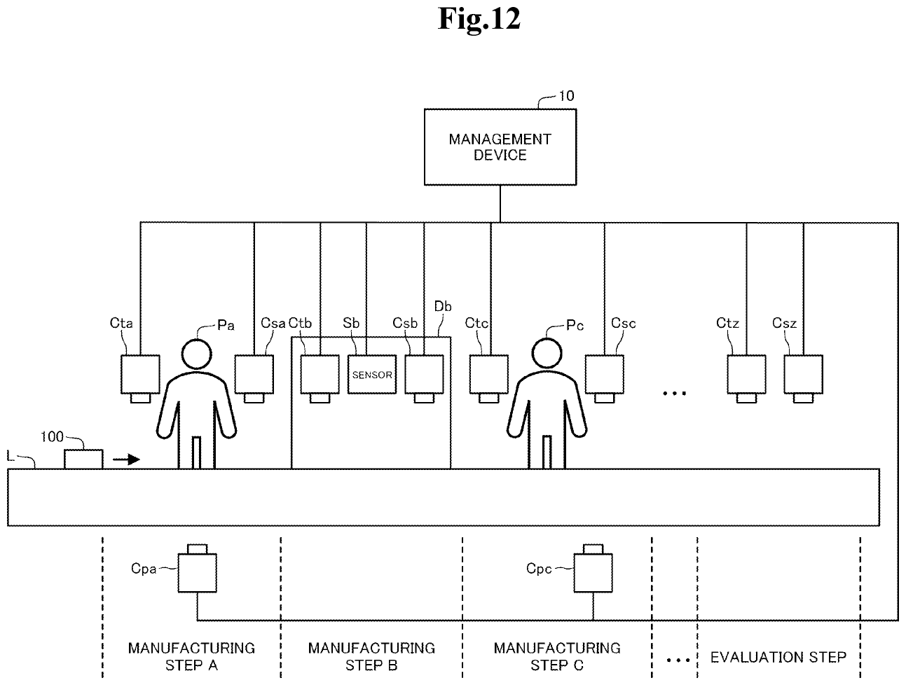

Next, a second exemplary embodiment of the present invention will be described with reference to FIGS. 12 to 15. A manufacturing system of the present embodiment further includes the configuration provided below, in addition to the manufacturing system described in the first exemplary embodiment. In the below description, a configuration different from that of the first exemplary embodiment will be mainly described.

As illustrated in FIG. 12, the manufacturing system of the present embodiment further includes cameras Csa, Csb, and Csc for capturing product that capture images of the product G, in the manufacturing steps A, B, and C, respectively. The cameras Csa, Csb, and Csc are installed so as to capture the entire product G in the respective manufacturing steps, and transmit captured images to the management device 10.

In the respective manufacturing steps A, B, and C, the acquisition unit 11 of the present embodiment acquires the object fingerprint and the parameters as described above and also acquires product images transmitted from the cameras Csa, Csb, and Csc for capturing the product.

The accumulation unit 12 (association unit) of the present embodiment stores the object fingerprint of the product G acquired by the acquisition unit 11 described above, the parameters representing the manufacturing states of the product G, and the product images of the product G, in the manufacturing parameter storage unit 17 in association with one another. Here, the accumulation unit 12 stores the object fingerprint, the parameter, and the product image acquired in the same manufacturing step, in association with one another. That is, the accumulation unit 12 associates the object fingerprint, the parameter, and the product image acquired by the acquisition unit 11 as described above at almost the same timing, in the same manufacturing step. Further, when the object fingerprints of the product G acquired in different manufacturing steps match, the accumulation unit 12 collectively store the parameters acquired in the respective manufacturing steps in association with one object fingerprint. Thereby, the parameter representing the manufacturing state and the product image in each manufacturing step of the same product G can be collectively stored in association with each other.

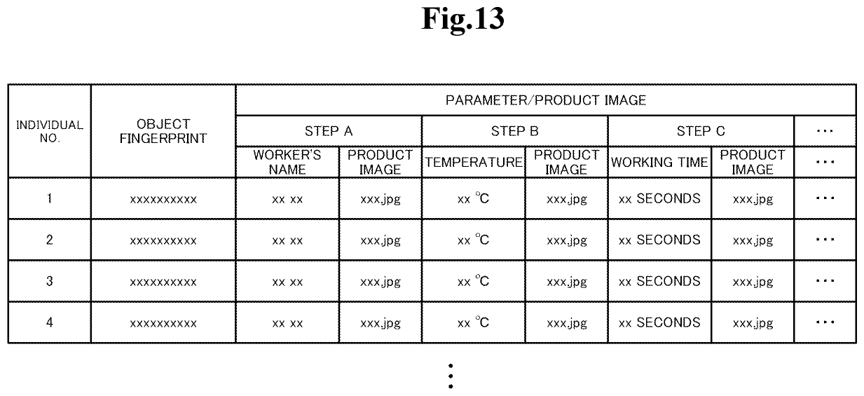

Specifically, the accumulation unit 12 acquires an object fingerprint, the parameter, and the product image from the acquisition unit 11, and when an object fingerprint that is identical to such an object fingerprint is not stored in the manufacturing parameter storage unit 17, gives a new individual number, and associates the object fingerprint, the parameter, and the product image with the individual number and stores them. Meanwhile, when an object fingerprint that is identical to the acquired object fingerprint is stored in the manufacturing parameter storage unit 17, the accumulation unit 12 stores the parameter and the product image by additionally associating them with the individual number associated with the stored object fingerprint. Thereby, as illustrated in FIG. 13, one individual number is given to one object fingerprint, and further, a parameter and a product image of each working step is stored in association therewith.

Then, the evaluation unit 13 of the present embodiment evaluates the product G as similar to the above-described case, and checks whether or not an object fingerprint identical to the object fingerprint acquired from the evaluated product G is stored in the manufacturing parameter storage unit 17. Then, when the identical object fingerprint is stored in the manufacturing parameter storage unit 17, the evaluation unit 13 reads the parameters and the product images in the manufacturing steps associated with the individual number given to the identical object fingerprint. Note that for each evaluation of the product G, the evaluation unit 13 may read the parameters representing the manufacturing states in the manufacturing steps of the product G from the manufacturing parameter storage unit 17. For example, the evaluation unit may separately read the parameters and the product images of a product G group evaluated to be in an abnormal condition, or the parameters and the product images of a product G group evaluated to be in a normal condition, for each evaluation.

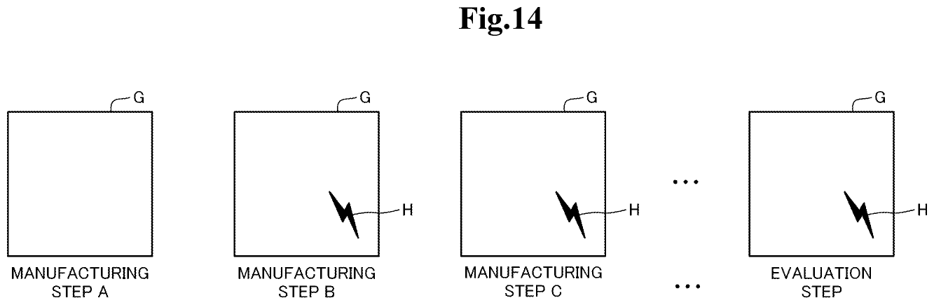

The specifying unit 14 of the present embodiment specifies manufacturing states such as parameters and manufacturing steps serving as a factor of evaluation of the product G, on the basis of the product image of each manufacturing step of the product G read out by the evaluation unit 13. For example, in a state where the product G is evaluated to be in an abnormal condition because it has a crack H from a product image at the time of evaluation step shown at the right end of FIG. 14, it is assumed that the product images at the manufacturing steps A, B, and C of the same product G are read out as shown in FIG. 14. In that case, by performing image processing to compare the product image at the time of evaluation step and the product images at the manufacturing steps A, B, and C, it is possible to specify the step name of the manufacturing step B in which the crack H begins to appear and the “temperature” that is a parameter representing the manufacturing state at that time, as a factor of evaluation of an abnormal condition.

Note that the specifying unit 14 may specify the manufacturing state such as a parameter and a manufacturing step serving as a factor of evaluation of the product G, from the product images of a product G group for each evaluation. For example, the specifying unit 14 compares product images of a product G group of one evaluation type with product images of a product G group of another evaluation type, and specifies a correlation between the content of the evaluation of the product G and a product image of each manufacturing step. Then, from a product image specified to have a correlation with evaluation, a manufacturing step and a parameter serving as the factor of the evaluation is specified.

Then, the output unit 15 of the present embodiment outputs, from an output device such as a display device, the parameter and the product image at the manufacturing step of the product G read out by the evaluation unit 13 as described above, or the product image and the parameter having a correlation with the evaluation of the product G specified by the specifying unit 14.

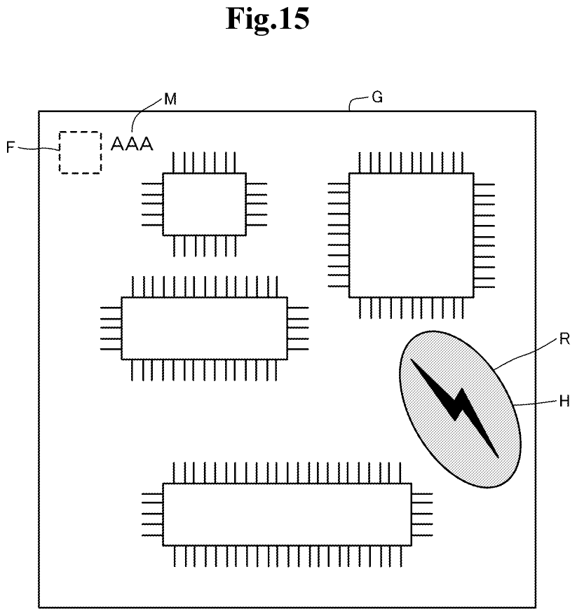

Further, the output unit 15 may display a product image of each manufacturing step while including therein information of a parameter representing the manufacturing state. For example, in a specific manufacturing step, when a thermography for measuring heat distribution of the product G is provided as a manufacturing state acquisition device, it is possible to acquire heat distribution of the product G as a parameter representing the manufacturing state in the specific manufacturing step. In that case, the heat distribution of the product G is displayed by being superimposed on the product image of the product G acquired in the specific manufacturing step. As an example, in FIG. 15, a product image of the product Gin a specific manufacturing step is shown. On the basis of heat distribution that is a parameter acquired in the specific manufacturing step, an area R having a higher temperature than a preset threshold is shown by being superimposed on the product image, as indicated by a reference sign R. Note than the output unit 15 may include any parameter in a product image and display and output it.

As described above, in the present embodiment, in each manufacturing step of the product G, the object fingerprint that is unique information of the product G, the parameters representing the manufacturing states in the manufacturing steps, and the product images in the manufacturing steps are acquired, and the object fingerprint, the parameter, and the product image acquired in the same manufacturing step are stored in association with one another. Therefore, the parameters and the product images in the manufacturing steps of the same product G can be collectively stored in association.

Then, in the present embodiment, the object fingerprint of the product G is acquired even in the evaluation step of the product G. Thereby, with use of such an object fingerprint, it is possible to read out the parameter and the product image at each of the manufacturing steps of the product G stored in association with the identical object fingerprint, and to check the product image of each manufacturing step corresponding to the evaluation of the product retroactively.

Therefore, it is possible to specify the factor of the evaluation of the product from the product image.

### Third Exemplary Embodiment

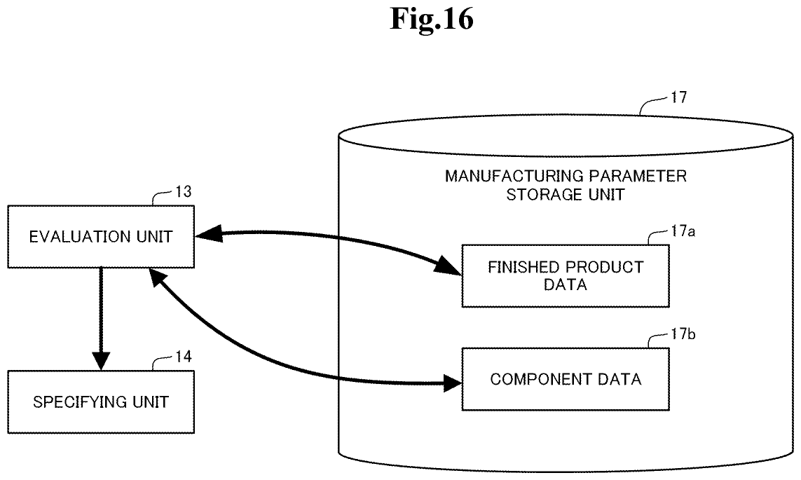

Next, a third exemplary embodiment of the present invention will be described with reference to FIG. 16. A manufacturing system of the present embodiment further includes the configuration provided below, in addition to the manufacturing system described in the first or second exemplary embodiment. In the below description, a configuration different from that of the first or second exemplary embodiment will be mainly described.

FIG. 16 illustrates part of the configuration of the management device 10 constituting the manufacturing system of the present embodiment. As illustrated in FIG. 16, the manufacturing parameter storage unit 17 of the present embodiment stores therein finished product data 17a that is information such as a parameter of each manufacturing step of a finished product that is the product G described above, and component data 17b that is information such as a parameter of each manufacturing step of a component constituting the product G, separately. For example, the finished product data 17a is information of a parameter of each manufacturing step of a semiconductor substrate that is the product G described above as illustrated in FIG. 4, and the component data 17a is information of a parameter of each manufacturing step such as a substrate body or an IC chip constituting the semiconductor substrate that is the product G described above. Note that the component data 17a is accumulated in advance as information of a parameter as illustrated in FIG. 4, by the acquisition unit 11 and the accumulation unit 12 of the management device 10 described above, when the substrate body or the IC chip is manufactured.

Then, the evaluation unit 13 of the present embodiment performs evaluation of the product G as similar to the case described above, and acquires an object fingerprint from a component constituting the product G. For example, when the product G is a semiconductor substrate, an object fingerprint of the substrate itself is acquired from an image in which the substrate itself, that is, a component, is captured. At that time, as an object fingerprint of the substrate itself that is a component, it is assumed that the evaluation unit 13 uses the object fingerprint of the semiconductor substrate that is the product G acquired in the evaluation step. However, the evaluation unit 13 may newly acquire the object fingerprint of a component such as a substrate body or an IC chip from another image area of an image in which the semiconductor substrate that is the product G is captured.

Then, the evaluation unit 13 checks whether or not an object fingerprint identical to the object fingerprint acquired from the product G is stored in the manufacturing parameter storage unit 17. At that time, the evaluation unit 13 checks whether or not the identical object fingerprint is stored in the component data 17b in the manufacturing parameter storage unit 17. Then, the evaluation unit 13 reads the parameter in the manufacturing steps associated with the identical object fingerprint into the component data 17b. Thereby, the evaluation unit 13 can read the parameters representing the manufacturing states in the manufacturing steps at the time of manufacturing the substrate itself that is a component of the semiconductor substrate that is the product G.

Then, the specifying unit 14 of the present embodiment analyzes the parameter of each manufacturing step of the product G and the parameter of each manufacturing step of the component read out by the evaluation unit 13, and specifies manufacturing states such as a parameter and a manufacturing step serving as the factor of evaluation of the product G. Thereby, even in the case where the factor of evaluation of the product G is in the manufacturing step of the component of the product G, such a factor can be specified in detail.

Note that while the finished product data 17a and the component data 17b are stored in the manufacturing parameter storage unit 17 separately, when image areas from which an object fingerprint is read out are different between the product G and a component, the finished product data 17a and the component data 17b may not be stored separately. For example, in the case where a finished product is a semiconductor substrate, a component is an IC ship, and an image area from which an object fingerprint of the semiconductor substrate is extracted and an image area from which an object fingerprint of the IC ship is extracted are different from each other, the object fingerprints must be different. Therefore, even if a parameter of each manufacturing step of the semiconductor substrate that is a finished product and a parameter of each manufacturing step of the IC chip that is a component are accumulated in the manufacturing parameter storage unit 17 in a mixed manner, it is possible to appropriately read out the parameters of each manufacturing step of the finished product and the component in which object fingerprints are extracted in the evaluation step.

### Fourth Exemplary Embodiment

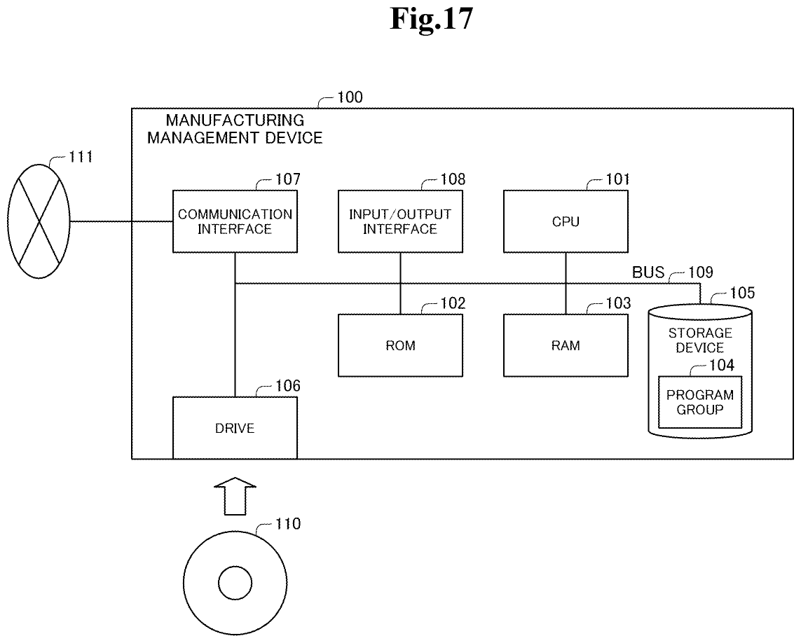

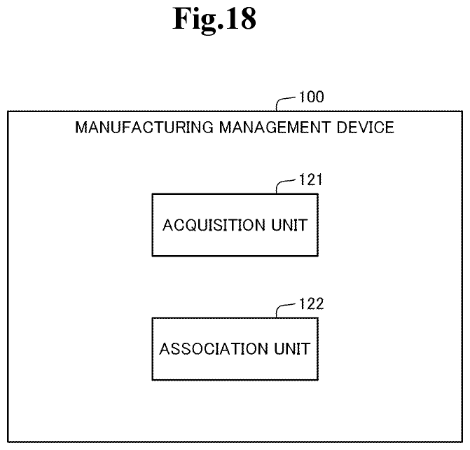

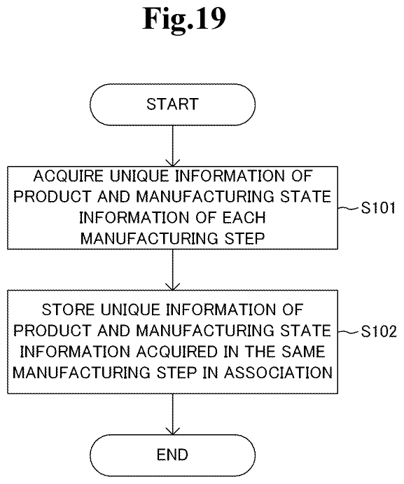

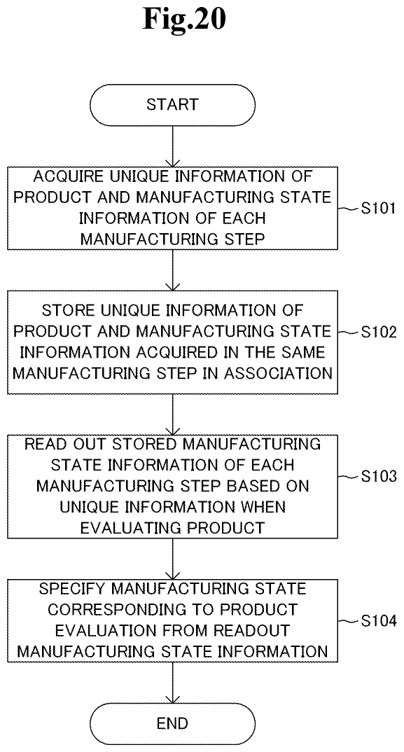

Next, a fourth exemplary embodiment of the present invention will be described with reference to FIGS. 17 to 20. FIGS. 17 and 18 are block diagrams illustrating the configuration of a manufacturing management device of the fourth exemplary embodiment, and FIGS. 19 and 20 are flowcharts illustrating the operation of the manufacturing management device. Note that the present embodiment shows the outlines of the management device 10 and the processing method performed by the management device 10 described in the first, second, and third exemplary embodiments.

First, a hardware configuration of the manufacturing management device 100 in the present embodiment will be described with reference to FIG. 17. The manufacturing management device 100 is configured of a typical information processing device, having a hardware configuration as described below as an example.
Central Processing Unit (CPU) 101 (arithmetic unit)
Read Only Memory (ROM) 102 (storage unit)
Random Access Memory (RAM) 103 (storage unit)
Program group 104 to be downloaded to the RAM 103
Storage device 105 storing therein the program group 104
Drive 106 that performs reading and writing on a storage medium 110 outside the information processing device
Communication interface 107 connecting to a communication network 111 outside the information processing device
Input/output interface 108 for performing input/output of data
Bus 109 connecting the constituent elements

The manufacturing management device 100 can construct, and can be equipped with, the acquisition unit 121 and the association unit 122 illustrated in FIG. 18 through acquisition and execution of the program group 104 by the CPU 101. Note that the program group 104 is stored in the storage device 105 or the ROM 102 in advance, and is loaded to the RAM 103 by the CPU 101 as needed. Further, the program group 104 may be provided to the CPU 101 via the communication network 111, or may be stored on a storage medium 110 in advance and read out by the drive 106 and supplied to the CPU 101. However, the acquisition unit 121 and the association unit 122 may be constructed by electronic circuits.

Note that FIG. 17 illustrates an example of the hardware configuration of the information processing device that is the manufacturing management device 100. The hardware configuration of the information processing device is not limited to that described above. For example, the information processing device may be configured of part of the configuration described above, such as without the drive 106.

The manufacturing management device 100 executes the manufacturing management method illustrated in the flowchart of FIG. 19 or FIG. 20, by the functions of the acquisition unit 121 and the association unit 122 constructed by the program as described above.

As illustrated in FIG. 19, the manufacturing management device 100 acquires unique information of a product from a captured image of the product for each manufacturing step included in a manufacturing process of the product, and acquires manufacturing state information representing a manufacturing state in the manufacturing step (step S101), and

stores the unique information of the product and the manufacturing state information that are acquired in an identical manufacturing step, in association with each other (step S102).

Further, as illustrated in FIG. 20, the manufacturing management device 100 acquires unique information of a product from a captured image of the product for each manufacturing step included in a manufacturing process of the product, and acquires manufacturing state information representing a manufacturing state in the manufacturing step (step S101), and

stores the unique information of the product and the manufacturing state information that are acquired in an identical manufacturing step, in association with each other (step S102);

when evaluating the product, acquires the unique information of the product from the captured image of the product, and reads out the manufacturing state information of each manufacturing step stored in association with unique information that is identical to the acquired unique information (step S103); and

specifies a manufacturing state corresponding to the evaluation of the product, on the basis of the readout manufacturing state information of each manufacturing step (step S104).

With the configuration described above, the present invention acquires, in each manufacturing step of a product, unique information of the product and manufacturing state information representing the manufacturing state in the manufacturing step, and stores them in association with each other. Therefore, the pieces of manufacturing state information in the respective manufacturing steps of the identical product can be collectively stored in association with each other.

Then, at the time of evaluating the product, the present invention acquires the unique information of the product, and with use of such unique information, reads out the manufacturing state information at the time of each manufacturing step of the product stored in association with the identical unique information. Thereby, it is possible to check the manufacturing state at the time of each manufacturing step corresponding to the evaluation of the product retroactively.

Further, the present invention specifies a manufacturing state corresponding to the evaluation of the product, on the basis of the readout manufacturing state information of each manufacturing step. Thereby, it is possible to specify the factor in the manufacturing steps of the quality of the product in detail.

### <Supplementary Notes>

The whole or part of the exemplary embodiments disclosed above can be described as the following supplementary notes. Hereinafter, outlines of the configurations of a manufacturing management method, a manufacturing management device, and a program, according to the present invention, will be described. However, the present invention is not limited to the configurations described below.

### (Supplementary Note 1)

A manufacturing management method comprising:

acquiring unique information of a product from a captured image of the product for each manufacturing step included in a manufacturing process of the product, and acquiring manufacturing state information representing a manufacturing state in the manufacturing step; and

storing the unique information of the product and the manufacturing state information, acquired in an identical manufacturing step, in association with each other;

when evaluating the product, acquiring the unique information of the product from the captured image of the product, and reading out the manufacturing state information of each manufacturing step stored in association with unique information that is identical to the acquired unique information; and

specifying a manufacturing state corresponding to the evaluation of the product, on a basis of the readout manufacturing state information of each manufacturing step.

### (Supplementary Note 2)

A manufacturing management method comprising:

acquiring unique information of a product from a captured image of the product for each manufacturing step included in a manufacturing process of the product, and acquiring manufacturing state information representing a manufacturing state in the manufacturing step; and

storing the unique information of the product and the manufacturing state information that are acquired in an identical manufacturing step in association with each other.

### (Supplementary Note 3)

The manufacturing management method according to supplementary note 2, further comprising

when evaluating the product, acquiring the unique information of the product from the captured image of the product, and reading out the manufacturing state information of each manufacturing step stored in association with unique information that is identical to the acquired unique information.

### (Supplementary Note 4)

The manufacturing management method according to supplementary note 3, further comprising

specifying a manufacturing state corresponding to the evaluation of the product, on a basis of the manufacturing state information of each manufacturing step that is read out when evaluating the product.

### (Supplementary Note 5)

The manufacturing management method according to supplementary note 4, further comprising

specifying a correlation between a content of the evaluation of the product and the manufacturing state information of each manufacturing step, on a basis of the manufacturing state information of each manufacturing step that is read out when evaluating the product for each product having a different evaluation content.

### (Supplementary Note 6)

The manufacturing management method according to any of supplementary notes 2 to 5, further comprising:

acquiring a product image in which the product is captured for each manufacturing step; and

storing the unique information of the product, the manufacturing state information, and the product image that are acquired in an identical manufacturing step, in association with one another.

### (Supplementary Note 7)

The manufacturing management method according to supplementary note 6, further comprising

reading out the manufacturing state information and the product image of each manufacturing step stored in association with unique information that is identical to the unique information of the product acquired when evaluating the product.

### (Supplementary Note 8)

The manufacturing management method according to supplementary note 7, further comprising

specifying a manufacturing state corresponding to the evaluation of the product, on a basis of the product image of each manufacturing step that is read out when evaluating the product.

### (Supplementary Note 9)

The manufacturing management method according to supplementary note 7 or 8, further comprising

displaying information representing a manufacturing state corresponding to the manufacturing state information while including the information in the product image, on a basis of the manufacturing state information and the product image of each manufacturing step that are read out when evaluating the product.

### (Supplementary Note 10)

The manufacturing management method according to any of supplementary notes 1 to 9, further comprising

on a basis of a result of evaluation of the product, specifying another product included in the product, acquiring unique information of the other product from a captured image of the other product, and reading out the manufacturing state information of each manufacturing step stored in association with unique information that is identical to the acquired unique information of the other product.

### (Supplementary Note 11)

A manufacturing management device comprising:

an acquisition unit that acquires unique information of a product from a captured image of the product for each manufacturing step included in a manufacturing process of the product, and acquires manufacturing state information representing a manufacturing state in the manufacturing step, and

an association unit that stores the unique information of the product and the manufacturing state information that are acquired in an identical manufacturing step in association with each other.

### (Supplementary Note 12)

The manufacturing management device according to supplementary note 11, further comprising

an evaluation unit that, when evaluating the product, acquires the unique information of the product from the captured image of the product, and reads out the manufacturing state information of each manufacturing step stored in association with unique information that is identical to the acquired unique information.

### (Supplementary Note 13)

The manufacturing management device according to supplementary note 12, further comprising

a specifying unit that specifies a manufacturing state corresponding to the evaluation of the product, on a basis of the manufacturing state information of each manufacturing step that is read out when the product is evaluated.

### (Supplementary Note 14)

The manufacturing management device according to claim 13, wherein

the specifying unit specifies a correlation between a content of the evaluation of the product and the manufacturing state information, on a basis of the manufacturing state information of each manufacturing step that is read out when each product having a different evaluation content is evaluated.

### (Supplementary Note 15)

The manufacturing management device according to any of supplementary notes 11 to 14, wherein

the acquisition unit acquires a product image in which a product is captured for each manufacturing step, and

the association unit stores the unique information of the product, the manufacturing state information, and the product image that are acquired in an identical manufacturing step, in association with one another.

### (Supplementary Note 16)

The manufacturing management device according to supplementary note 15, wherein

the evaluation unit reads out the manufacturing state information and the product image of each manufacturing step stored in association with unique information that is identical to the unique information of the product acquired when evaluating the product.

### (Supplementary Note 17)

The manufacturing management device according to supplementary note 16, wherein

the specifying unit specifies a manufacturing state corresponding to the evaluation of the product, on a basis of the product image of each manufacturing step that is read out when the product is evaluated.

### (Supplementary Note 18)

The manufacturing management device according to supplementary note 16 or 17, further comprising

an output unit that displays information representing a manufacturing state corresponding to the manufacturing state information while including the information in the product image, on a basis of the manufacturing state information and the product image of each manufacturing step that is read out when the product is evaluated.

### (Supplementary Note 19)

The manufacturing management device according to any of supplementary notes 11 to 18, wherein

on a basis of a result of evaluation of the product, the evaluation unit specifies another product included in the product, acquires unique information of the other product from a captured image of the other product, and reads out the manufacturing state information of each manufacturing step stored in association with unique information that is identical to the acquired unique information of the other product.

### (Supplementary Note 20)

A program for causing an information processing device to realize:

an acquisition unit that acquires unique information of a product from a captured image of the product for each manufacturing step included in a manufacturing process of the product, and acquires manufacturing state information representing a manufacturing state in the manufacturing step; and

an association unit that stores the unique information of the product and the manufacturing state information that are acquired in an identical manufacturing step in association with each other.

### (Supplementary Note 21)

The program according to supplementary note 20 for causing the information processing device to realize

an evaluation unit that, when evaluating the product, acquires the unique information of the product from the captured image of the product, and reads out the manufacturing state information of each manufacturing step stored in association with unique information that is identical to the acquired unique information.

### (Supplementary Note 22)

The program according to supplementary note 21 for causing the information processing device to realize

a specifying unit that specifies a manufacturing state corresponding to the evaluation of the product, on a basis of the manufacturing state information of each manufacturing step that is read out when the product is evaluated.

Note that the program described above can be supplied to a computer by being stored in a non-transitory computer-readable medium of any type. Non-transitory computer-readable media include tangible storage media of various types. Examples of non-transitory computer-readable media include a magnetic storage medium (for example, flexible disk, magnetic tape, hard disk drive), a magneto-optical storage medium (for example, magneto-optical disk), a CD-ROM (Read Only Memory). a CD-R, a CD-R/W, a semiconductor memory (for example, mask ROM, PROM (Programmable ROM), and EPROM (Erasable PROM), a flash ROM, and a RAM (Random Access Memory)). Note that the program may be supplied to a computer by being stored in a transitory computer-readable medium of any type. Examples of transitory computer-readable media include an electric signal, an optical signal, and an electromagnetic wave. A transitory computer-readable medium can be supplied to a computer via wired communication channel such as a wire and an optical fiber, or a wireless communication channel.

While the present invention has been described with reference to the exemplary embodiments described above, the present invention is not limited to the above-described embodiments. The form and details of the present invention can be changed within the scope of the present invention in various manners that can be understood by those skilled in the art.

### REFERENCE SIGNS LIST

10 management device
11 acquisition unit
12 accumulation unit
13 evaluation unit
14 specifying unit
15 output unit
16 step data storage unit
17 manufacturing parameter storage unit
18 evaluation data storage unit
100 manufacturing management device
101 CPU
102 ROM
103 RAM
104 program group
105 storage device
106 drive
107 communication interface
108 input/output interface
109 bus
110 storage medium
111 communication network
121 acquisition unit
122 association unit cm What is claimed is:

1. (canceled)

2. A manufacturing management method comprising:
acquiring unique information of a product from a captured image of the product for each manufacturing step included in a manufacturing process of the product, and acquiring manufacturing state information representing a manufacturing state in the manufacturing step; and
storing the unique information of the product and the manufacturing state information that are acquired in an identical manufacturing step in association with each other.

3. The manufacturing management method according to claim 2, further comprising
when evaluating the product, acquiring the unique information of the product from the captured image of the product, and reading out the manufacturing state information of each manufacturing step stored in association with unique information that is identical to the acquired unique information.

4. The manufacturing management method according to claim 3, further comprising
specifying a manufacturing state corresponding to the evaluation of the product, on a basis of the manufacturing state information of each manufacturing step that is read out when evaluating the product.

5. The manufacturing management method according to claim 4, further comprising
specifying a correlation between a content of the evaluation of the product and the manufacturing state information of each manufacturing step, on a basis of the manufacturing state information of each manufacturing step that is read out when evaluating the product for each product having a different evaluation content.

6. The manufacturing management method according to claim 2, further comprising:
acquiring a product image in which the product is captured for each manufacturing step; and
storing the unique information of the product, the manufacturing state information, and the product image that are acquired in an identical manufacturing step, in association with one another.

7. The manufacturing management method according to claim 6, further comprising
reading out the manufacturing state information and the product image of each manufacturing step stored in association with unique information that is identical to the unique information of the product acquired when evaluating the product.

8. The manufacturing management method according to claim 7, further comprising
specifying a manufacturing state corresponding to the evaluation of the product, on a basis of the product image of each manufacturing step that is read out when evaluating the product.

9. The manufacturing management method according to claim 7, further comprising
displaying information representing a manufacturing state corresponding to the manufacturing state information while including the information in the product image, on a basis of the manufacturing state information and the product image of each manufacturing step that are read out when evaluating the product.

10. The manufacturing management method according to claim 2, further comprising
on a basis of a result of evaluation of the product, specifying another product included in the product, acquiring unique information of the other product from a captured image of the other product, and reading out the manufacturing state information of each manufacturing step stored in association with unique information that is identical to the acquired unique information of the other product.

11. A manufacturing management device comprising:
at least one memory configured to store instructions; and
at least one processor configured to execute instructions to:
acquire unique information of a product from a captured image of the product for each manufacturing step included in a manufacturing process of the product, and acquire manufacturing state information representing a manufacturing state in the manufacturing step, and
store the unique information of the product and the manufacturing state information that are acquired in an identical manufacturing step in association with each other.

12. The manufacturing management device according to claim 11, wherein the at least one processor is configured to execute the instructions to
when evaluating the product, acquire the unique information of the product from the captured image of the product, and read out the manufacturing state information of each manufacturing step stored in association with unique information that is identical to the acquired unique information.

13. The manufacturing management device according to claim 12, wherein the at least one processor is configured to execute the instructions to
specify a manufacturing state corresponding to the evaluation of the product, on a basis of the manufacturing state information of each manufacturing step that is read out when the product is evaluated.

14. The manufacturing management device according to claim 13, wherein the at least one processor is configured to execute the instructions to
specify a correlation between a content of the evaluation of the product and the manufacturing state information, on a basis of the manufacturing state information of each manufacturing step that is read out when each product having a different evaluation content is evaluated.

15. The manufacturing management device according to any of claims 11 to 14, wherein the at least one processor is configured to execute the instructions to:
acquire a product image in which a product is captured for each manufacturing step, and
store the unique information of the product, the manufacturing state information, and the product image that are acquired in an identical manufacturing step, in association with one another.

16. The manufacturing management device according to claim 15, wherein the at least one processor is configured to execute the instructions to
read out the manufacturing state information and the product image of each manufacturing step stored in association with unique information that is identical to the unique information of the product acquired when evaluating the product.

17. The manufacturing management device according to claim 16, wherein the at least one processor is configured to execute the instructions to
specify a manufacturing state corresponding to the evaluation of the product, on a basis of the product image of each manufacturing step that is read out when the product is evaluated.

18. The manufacturing management device according to claim 16, wherein the at least one processor is configured to execute the instructions to
display information representing a manufacturing state corresponding to the manufacturing state information while including the information in the product image, on a basis of the manufacturing state information and the product image of each manufacturing step that is read out when the product is evaluated.

19. The manufacturing management device according to claim 11, wherein the at least one processor is configured to execute the instructions to
on a basis of a result of evaluation of the product, specify another product included in the product, acquire unique information of the other product from a captured image of the other product, and read out the manufacturing state information of each manufacturing step stored in association with unique information that is identical to the acquired unique information of the other product.

20. A non-transitory computer-readable storage medium in which a program is stored the program comprising instructions for causing an information processing device to execute processing of:
acquiring unique information of a product from a captured image of the product for each manufacturing step included in a manufacturing process of the product, and acquiring manufacturing state information representing a manufacturing state in the manufacturing step; and
storing the unique information of the product and the manufacturing state information that are acquired in an identical manufacturing step in association with each other.
